(19) United States
(12) Patent Application Publication
(10) Pub. No.: US 2025/0275291 A1
(43) Pub. Date: Aug. 28, 2025

(54) SOLAR CELL HAVING ASSEMBLED TESSELLATION STRUCTURE

(71) Applicant: KOREA ELECTROTECHNOLOGY RESEARCH INSTITUTE, Gyeongsangnam-do (KR)

(72) Inventors: Min Ju YUN, Gyeongsangnam-do (KR); Seung Il CHA, Seoul (KR); Yeon Hyang SIM, Gyeongsangnam-do (KR); Dong Yoon LEE, Gyeongsangnam-do (KR)

(73) Assignee: KOREA ELECTROTECHNOLOGY RESEARCH INSTITUTE, Gyeongsangnam-do (KR)

(21) Appl. No.: 18/704,900

(22) PCT Filed: Dec. 3, 2021
(86) PCT No.: PCT/KR2021/018180

§ 371 Date: Apr. 25, 2024

(30) Foreign Application Priority Data
Oct. 27, 2021 (KR) 10-2021-0145051

(51) Int. Cl. H10F 77/20

(52) U.S. Cl. CPC H10F 77/215

(57) ABSTRACT

Proposed is a solar cell having an assembled tessellation structure, in more detail, a solar cell having an assembled tessellation structure that can be installed on various shapes of installation surface including a curved surface. The solar cell includes unit cells each formed in a flat polygonal plate shape and each having an electrode seat that is a groove formed on a rear surface thereof toward a side from a center of the flat plate, and electrodes each fitted in all of the electrode seats formed on two unit cells when the two unit cells are sequentially disposed to be in contact with each other on sides, wherein the unit cells and the electrodes are sequentially assembled through fitting like Lego blocks.

### TECHNICAL FIELD

The present disclosure relates to a solar cell having an assembled tessellation structure and, in more detail, a solar cell having an assembled tessellation structure that can be installed on installation surface having various shapes including a curved surface.

### BACKGROUND ART

Recently, as the necessity of developing new and renewable energy to solve problems of exhaustion of fossil fuel, environmental pollution, and global warming due to the exhaustion of fossil fuel and environmental pollution increases, solar cells that can be infinitely reused is in the spotlight. Further, the Korean government issued the policy “Renewable energy 3020” for reducing the ratio of coal power generation and nuclear power generation and increasing renewable energy power generation mainly including solar power generation and wind power generation up to 20%, so the new and renewable energy project is being carried out faster.

With such a tendency, a technology of producing energy by installing a solar cell module at the uppermost part of structures such as a building and the sunroof of a vehicle are being developed, but solar cell modules based on Glass-Ethylene Vinyl Acetate (EVA) of the related art are difficult to dispose on a curved structure because it is difficult to implement a flexible function due to the characteristics of the materials.

In order to solve this problem in the related art, a flexible solar cell to which a laminating process using a conductive flexible substrate and a film printed with an electrode circuit is applied such as Korean Patent No. 10-1775977 (Manufacturing method of flexible solar cell module and flexible solar cell module thereby) has been developed. This related art has the advantage that the solar cell module can be disposed on a curved structure, but has a is defect that durability low because unit cells constituting the solar cell are stacked. Further, in the related art, an electrode circuit is designed in a serial and parallel connection structure and the part at which an electrode circuit and cells are connected should be thicker than the cells to select a serial connection structure, so the manufacturing type should be differently applied in accordance with the installation environment and the use, and accordingly, it is required to develop a technology for solving this problem.

### DISCLOSURE

### Technical Problem

An objective of the present disclosure is to provide a solar cell having an assembled tessellation structure in which electrodes can be connected to unit cells through fitting like Lego blocks.

Another objective of the present disclosure is to provide a solar cell having an assembled tessellation structure in which the entire solar cell structure composed of unit cells and electrodes is formed in a plane shape because the electrodes are formed in a serpentine shape.

Another objective of the present disclosure is to provide a solar cell having an assembled tessellation structure in which unit cells can be implemented in various colors because it is possible to add dye in the process of manufacturing the unit cells.

Another objective of the present disclosure is to provide a solar cell having an assembled tessellation structure to which a connection circuit suitable for an installation environment can be applied.

### Technical Solution

A solar an assembled tessellation cell having structure of the present disclosure includes; unit cells each formed in a flat polygonal plate shape and each having an electrode seat that is a groove formed on a rear surface thereof toward a side from a center of the flat plate; and electrodes each fitted in all of the electrode seats formed on two unit cells when the two unit cells are sequentially disposed to be in contact with each other on sides, wherein the unit cells and the electrodes are sequentially assembled through fitting like Lego blocks.

In the solar cell having an assembled tessellation structure of the present disclosure, the electrode may be formed in a serpentine shape and an entire structure may be formed in a flexible plane shape when the unit cells and the electrodes are sequentially assembled like Lego blocks.

In the solar cell having an assembled tessellation structure of the present disclosure, the electrode seats each may be disposed perpendicular to a side from the center of the unit cell and may be connected to each other.

In the solar cell having an assembled tessellation structure of the present disclosure, the unit cell may be colored by adding dye to back frame epoxy in manufacturing.

In the solar cell having an assembled tessellation structure of the present disclosure, the unit cell may have any one shape selected from a triangle, a rectangle, and a hexagon.

### Advantageous Effects

According to the present disclosure, there is an effect of providing a solar cell having an assembled tessellation structure that can be easily manufactured by fitting electrodes like Lego blocks.

Further, since the electrode is formed in a serpentine structure, a structure formed by unit cells and electrodes is formed in a flexible plane shape, whereby there is an effect of providing a solar cell having an assembled tessellation structure that can be installed on a curved surface.

Further, there is an effect of providing a solar cell having an assembled tessellation structure in which unit cells can be colored by adding dye when manufacturing the unit cells.

Further, there is an effect of providing a solar cell having an assembled tessellation structure that enables selective application of connection circuits in accordance with installation environments because the solar cell is formed in a tessellation structure, and electrodes and unit cells are fitted like Lego blocks.

### DESCRIPTION OF DRAWINGS

FIG. 1 is a perspective view showing the assembled state of a unit cell and an electrode in a solar cell having an assembled tessellation structure of the present disclosure.

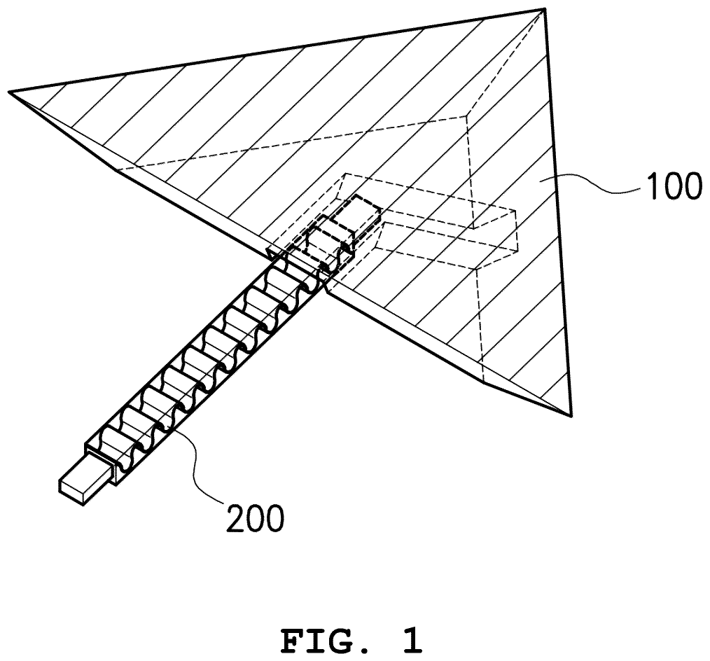

FIG. 2 is a rear view showing an assembled state of two unit cells and an electrode in the solar cell having an assembled tessellation structure of the present disclosure.

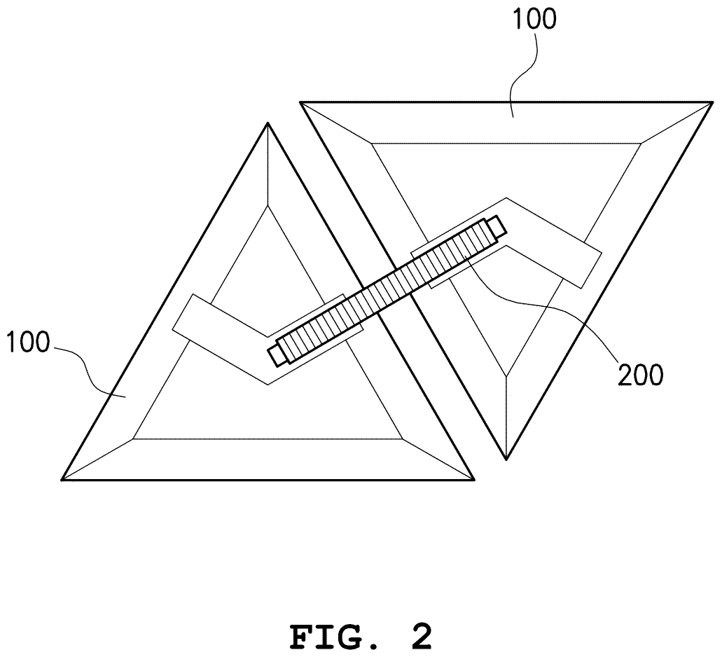

FIG. 3 is a view showing an assembled state of unit cells and electrodes disposed in a tessellation structure in the solar cell having an assembled tessellation structure of the present disclosure.

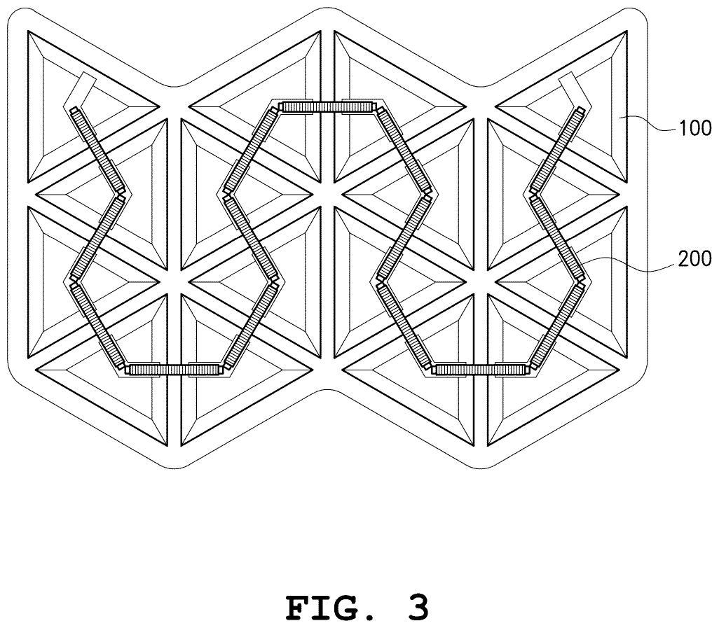

FIG. 4 is a view showing the state in which the solar cell having an assembled tessellation structure of the present disclosure has been installed on a curved surface.

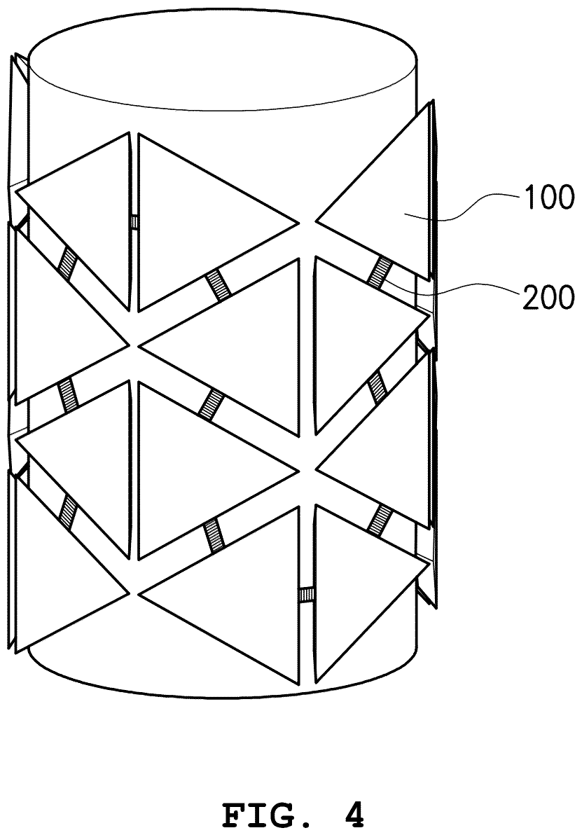

FIG. 5 is a view showing a process of assembling the solar cell having an assembled tessellation structure of the present disclosure.

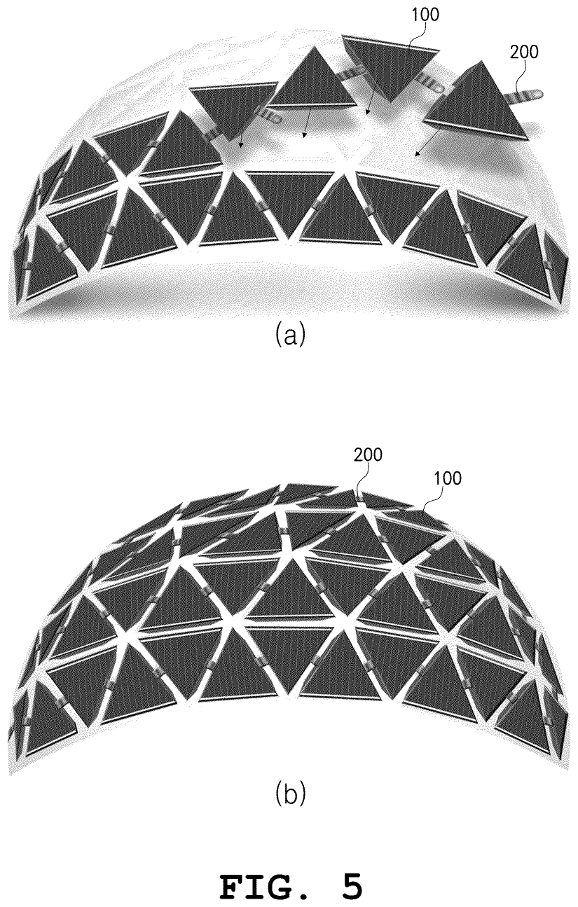

FIG. 6 is a rear view showing an embodiment in which unit cells formed in hexagonal shapes are coupled to an electrode in the solar cell having an assembled tessellation structure of the present disclosure.

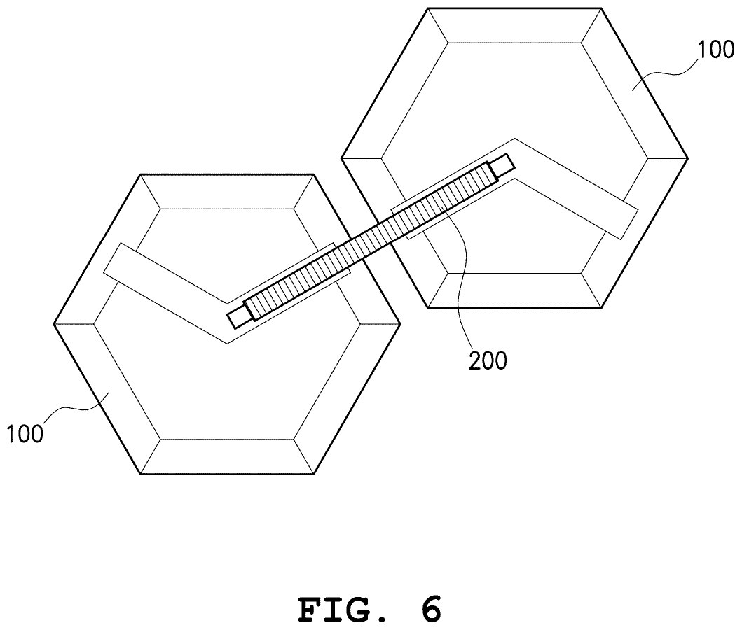

FIG. 7 is a perspective view showing the configuration of an electrode in the solar cell having an assembled tessellation structure of the present disclosure.

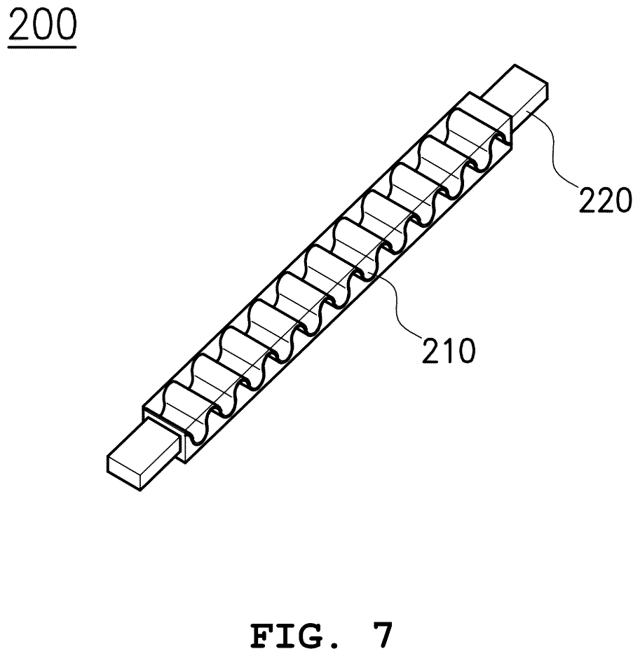

### BEST MODE

Hereinafter, embodiments of the present disclosure will be described in detail with reference to the accompanying drawings. Meanwhile, the configuration and operation that those skilled in the art can easily know from common solar cells, modules, cells, and electrodes are briefly shown and described or omitted in the drawings and the detailed description. In particular, detailed technical configuration and operation of elements that are not directly related to the technical features of the present disclosure are not described or shown in detail in the drawings and the detailed description and only the technical configuration related to the present disclosure is briefly shown or described.

A solar cell having an assembled tessellation structure of the present disclosure includes unit cells 100 and electrodes, in which the unit cells 100 and the electrodes are continuously assembled through fitting such as Lego blocks.

The unit cell 100 has a polygonal flat plate shape and has an electrode seat 110 formed on the rear surface thereof.

The electrode seat 110 is formed toward a side from the center of the flat rear surface of the unit cell 100.

The electrode seats 110 each may be perpendicular to a side from the center of the unit cell 100 and may be connected to each other.

The unit cell 100 may be encapsulated as a single piece from the front surface of a back frame to the front sheet, which may be achieved through a one-step process.

The encapsulation material of the unit cell 100 may be a polymer.

The unit cell 100 may be colored by adding dye to back frame epoxy in manufacturing.

When two unit cells 100 are sequentially disposed to be in contact with each other on sides thereof, the electrode 200 is fitted in all of the electrode seats 110 formed by the unit cells 110, whereby a plurality of unit cells 100 is electrically connected.

In this case, an end and another end of the electrode 200 may be disposed at the centers of electrode seats 110 of the unit cells 100, respectively.

The electrode 200 is formed in a serpentine shape, so when a unit cell 100 and an electrode 200 are sequentially assembled like Lego blocks, the entire structure may be formed in a flexible plane shape.

The serpentine shape may be understood as a wavy structure that meanders.

The electrode 200 may be divided into a connection portion 210 and electrode ends 220.

The connection portion 210 may be made of metal in a serpentine shape and may be encapsulated by a polymer having flexibility.

In this configuration, the metal connecting the electrode ends 220 is capsulated, whereby durability can be improved.

The smaller the electrical resistance, the more the connection portion 210 is advantageous to minimize an electrical loss, and the connection portion 210 may be made of a flexible material.

The electrode ends 220 are formed at both ends of the connection portion 210 and may be fixed to the electrode seat 110 formed on the rear surface of the unit cell 100.

That is, according to the solar cell having an assembled tessellation structure of the present disclosure, the unit cell 100 and the electrode 200 are formed as pieces so that they can be fitted to each other like Lego blocks, so the solar cell can be formed in a solar cell structure by sequentially assembling the unit cells and the electrodes.

A tessellation structure can be formed by sequentially disposing a plurality of unit cells 100 of the present disclosure.

Tessellation is a structure formed by collecting flat figures without a gap and an overlap and may be classified into regular tessellation, semiregular tessellation, and irregular tessellation.

The regular tessellation means tessellation composed of one-type regular polygons and the figures constituting tessellation may be a regular triangle, a regular square, and a regular hexagon.

In order to form such a tessellation structure using a plurality of unit cells 100, the unit cells 100 should be formed in polygonal shapes. The unit cells of the solar cell having an assembled tessellation structure may be formed in any one shape selected from a triangle, a rectangle, and a hexagon of polygons that can form regular tessellation.

The solar cell having an assembled tessellation structure having this configuration is formed in a tessellation structure such that the electrode 200 can be fitted to the unit cell 100 like Lego blocks, so it is possible to connect the unit cell 100 and the electrode 200 in series, in parallel, or in series-parallel regardless of directions.

That is, the solar cell having an assembled tessellation structure of the present disclosure is formed such that a circuit of a series, a parallel, and a series-parallel can be selected and connected, depending on the installation environment.

As an embodiment, the sunlight is a direct ray and light that travels to unit cells is not uniform in a curved solar cell, so there is a defect that the output decreases when a serial connection circuit is selected, so a serial-parallel connection circuit may be selected. According to the solar cell having an assembled tessellation structure, the unit cells 100 can be disposed in a tessellation structure and the electrodes 200 are fitted like Lego blocks to the rear surfaces of the unit cells 100, whereby it is possible to more freely select connection structures.

A solar cell having an assembled tessellation structure according to an embodiment of the present disclosure was described above and shown in the figures, but this is only an example and it would be easily understood by those skilled in the art that the present disclosure can be changed and modified in various ways without departing from the spirit of the present disclosure.

1. A solar cell having an assembled tessellation structure, the solar cell comprising:
unit cells each formed in a flat polygonal plate shape and each having an electrode seat that is a groove formed on a rear surface thereof toward a side from a center of the flat plate; and
electrodes each fitted in all of the electrode seats formed on two unit cells when the two unit cells are sequentially disposed to be in contact with each other on sides,
wherein the unit cells and the electrodes are sequentially assembled through fitting like Lego blocks.

2. The solar cell of claim 1, wherein the electrode is formed in a serpentine shape, and
an entire structure is formed in a flexible plane shape when the unit cells and the electrodes are sequentially assembled like Lego blocks.

3. The solar cell of claim 1, wherein the electrode seats are each disposed perpendicular to a side from the center of the unit cell and are connected to each other.

4. The solar cell of claim 1, wherein the unit cell can be colored by adding dye to back frame epoxy in manufacturing.

5. The solar cell of claim 1, wherein the unit cell has any one shape selected from a triangle, a rectangle, and a hexagon.
